(19) United States
(12) Patent Application Publication
(10) Pub. No.: US 2012/0234590 A1
(43) Pub. Date: Sep. 20, 2012

(54) PRINTED CIRCUIT BOARD

(75) Inventors: MING WEI, Shenzhen City (CN); NING LI, Shenzhen City (CN); CHIA-NAN PAI, Tu-Cheng (TW); SHOU-KUO HSU, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/095,853

(22) Filed: Apr. 28, 2011

(30) Foreign Application Priority Data
Mar. 15, 2011 (CN) 201110061980.2

(51) Int. Cl. H05K 1/11

(52) U.S. Cl. 174/262

(57) ABSTRACT

A printed circuit board includes first to sixth layers, and first to third traces. The first trace is arranged on the first layer. The second trace is arranged on the third layer. The third trace is arranged on the sixth layer. The second trace is electrically connected to the first trace through a first vertical interconnection access (via). The second trace is electrically connected to the third trace through a second via.

### BACKGROUND

1. Technical Field

The present disclosure relates to a printed circuit board (PCB).

2. Description of Related Art

Multi-layer PCBs are used for motherboards. The multi-layer PCB includes a number of signal layers having transmission lines or traces. Signals are transmitted from one signal layer to another signal layer through vertical interconnection accesses (vias). However, impedance of the vias may not match the impedance of the traces, this influence signal integrity.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a sectional view of an exemplary embodiment of a printed circuit board.

FIG. 2 is a simulation graph of insertion loss of the printed circuit board of FIG. 1 and a conventional printed circuit board.

FIG. 3 is a simulation graph of impedance matching of the printed circuit board of FIG. 1 and a conventional printed circuit board.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

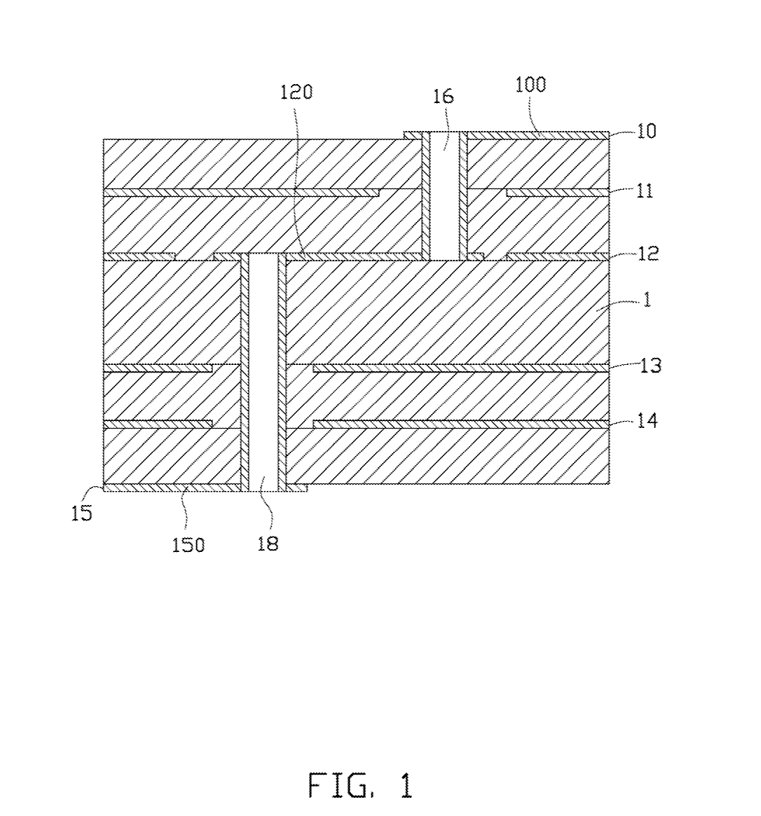

Referring to FIG. 1, an exemplary embodiment of a printed circuit board (PCB) is shown. The PCB includes dielectric materials 1 respectively sandwiched between adjacent first to sixth layers 10-15 of etched copper foil. The conductive copper pathways that remain after etching are called transmission lines or traces. The dielectric material 1 insulates two adjacent etched copper layers from each other. In the embodiment, the first layer 10 and the sixth layer 15 are signal layers. The second to fifth layers 11-14 are reference layers which include ground layers and power layers.

A first trace 100 is arranged on the first layer 10. A first terminal of the first trace 100 is used to receive electrical signals. A second terminal of the first trace 100 is electrically connected to a first vertical interconnection access (via) 16. The first via 16 extends through the first layer 10, the second layer 11, and the third layer 12. The first via 16 is electrically connected to the first layer 10 and the third layer 12, but is insulated from the second layer 12.

A second via 18 extends through the third to sixth layers 12-15, and is insulated from the third to fifth layers 12-14. The second via 18 is electrically connected to the sixth layer 15.

A second trace 120 is arranged on the third layer 12. A first terminal of the second trace 120 is electrically connected to the first via 16. A second terminal of the second trace 120 is electrically connected to the second via 18. A third trace 150 is arranged on the sixth layer 15. A first terminal of the third trace 150 is electrically connected to the second via 18. A second terminal of the third trace 150 is used to output the electrical signals. As a result, the electrical signals on the first layer 10 can be transmitted to the sixth layer 15 through the first trace 100, the first via 16, the second trace 120, the second via 18, and the third trace 150 in that order.

Because the second trace 120 is set between the first via 16 and the second via 18, an impedance of a transmission path from the first layer 10 to the sixth layer 15 becomes greater. In the embodiment, the impedance of the transmission path from the first layer 10 to the sixth layer 15 is the sum of the impedance of the first via 16, the second trace 120, and the second via 18. Moreover, a width of the second trace 120 can be changed to change the impedance of the second trace 120, thus changing the impedance of the transmission path from the first layer 10 to the sixth layer 15. As a result, the impedance of the first trace 100 and the third trace 150 can match the impedance of the transmission path, namely the impedance of the first via 16, the second trace 120, and the second via 18.

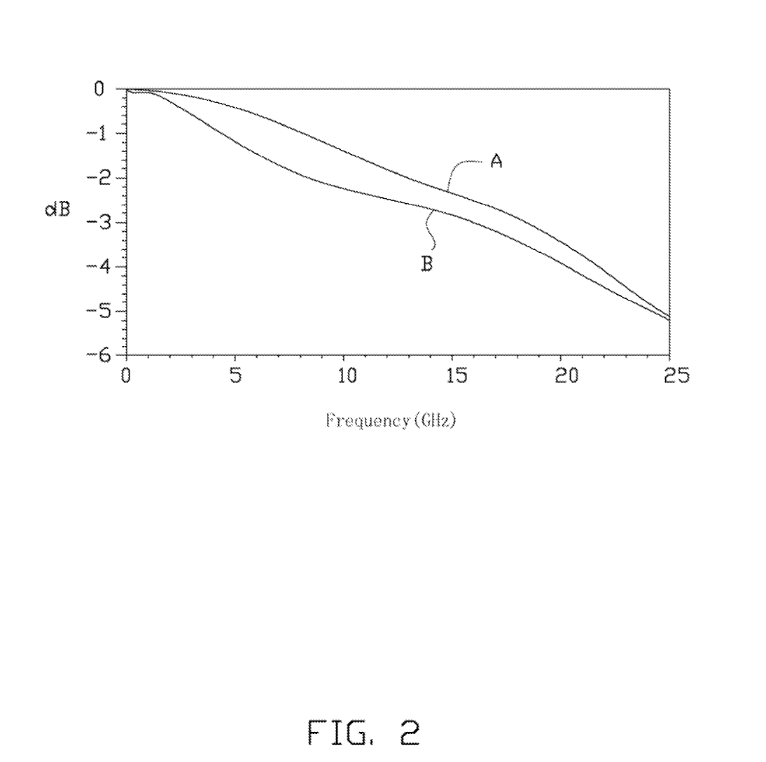

Referring to FIG. 2, a curve A in FIG. 2 shows a simulation graph of insertion loss of the printed circuit board 1, and a curve B in FIG. 2 shows a simulation graph of insertion loss of a conventional printed circuit board. As shown in FIG. 2, the insertion loss of the printed circuit board is less than the insertion loss of the conventionally printed circuit board as the frequencies of the signals on the traces of the printed circuit board increases.

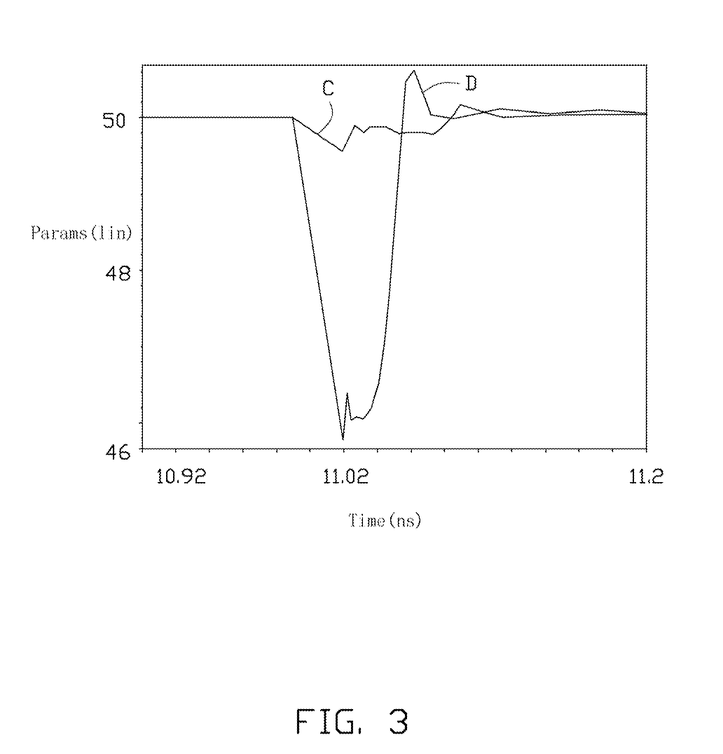

Referring to FIG. 3, a curve C in FIG. 3 shows a simulation graph of impedance matching of the printed circuit board 1, and a curve D in FIG. 3 shows a simulation graph of impedance matching of the conventionally printed circuit board. As shown in FIG. 3, the impedance matching of the printed circuit board is better than the impedance matching of the conventionally printed circuit board.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A printed circuit board comprising:
first to sixth layers;
a first trace arranged on the first layer, wherein a first terminal of the first trace is operable to receive electrical signals;
a second trace arranged on the third layer; and
a third trace arranged on the sixth layer, wherein a first terminal of the second trace is electrically connected to a second terminal of the first trace through a first vertical interconnection accesses (via), a second terminal of the second trace is electrically connected to a first terminal of the third trace through a second via, a second terminal of the third trace is operable to output the electrical signals.

2. The printed circuit board of claim 1, wherein the first via and the second via are blind vias.

3. The printed circuit board of claim 1, wherein the first via extends through the first layer, the second layer, and the third layer, the first via is insulated from the second layer.

4. The printed circuit board of claim 1, wherein the second via extends through the third layer, the fourth layer, the fifth layer, and the sixth layer, the second via is insulated from the fourth layer and the fifth layer.

5. The printed circuit board of claim 1, wherein impedance of the first via, the second trace, and the second via matches impedance of the first trace and the third trace.
